(19) United States
(12) Patent Application Publication
(10) Pub. No.: US 2026/0100694 A1
(43) Pub. Date: Apr. 9, 2026

(54) Designing a Plurality of Frequency Filters Distributed in a Vehicle On-Board Power Supply System

(71) Applicant: BAYERISCHE MOTOREN WERKE AKTIENGESELLSCHAFT, München (DE)

(72) Inventor: Martin BAUMANN, Muenchen (DE)

(21) Appl. No.: 19/113,982

(22) PCT Filed: Aug. 11, 2023
(86) PCT No.: PCT/EP2023/072283

§ 371 Date: Mar. 21, 2025

(30) Foreign Application Priority Data
Sep. 23, 2022 (DE) 10 2022 124 563.2

(51) Int. Cl. H03H 11/04; B60L 1/00; G06F 30/373

(52) U.S. Cl. CPC H03H 11/04; B60L 1/003; G06F 30/373

(57) ABSTRACT

A method for designing frequency filters, includes (a) setting up a simulation model of a power supply system with frequency filters; (b) determining initial set of filter parameters; (c) calculating the model using the filter parameters in time domain; (d) extracting safety-critical trajectories from the calculated model with underlying interference functions; (e) transforming safety-critical trajectories from time domain into frequency domain; (f) determining transfer functions in s-domain by system identification; (g) extracting pairs of residuals and poles based on transfer functions in s-domain; (h) determining energy loss and voltage stability values based on the residuals and poles; (i) varying the filter parameters; (j) repeating (c)-(h) with the filter parameters varied in step (i), until a termination criterion is reached; (k) after which, selecting, from a set of points with energy loss and voltage stability values determined in step (h), a point lying on a pareto-front of the set of points.

### BACKGROUND AND SUMMARY

The present disclosure relates to a method for designing a plurality of frequency filters which are distributed in an on-board power supply system of a vehicle, comprising at least a step for setting up a simulation model of the on-board power supply system having a given number of frequency filters at defined locations of the on-board power supply system. The present disclosure also relates to an on-board power supply system of a vehicle having a plurality of distributed frequency filters, wherein the frequency filters are determined via the method. The present disclosure further relates to a vehicle having an on-board power supply system of this type. The present disclosure, in particular, is advantageously applicable to fully electrically powered vehicles.

On-board power supply systems of vehicles are comprised of locally extended cable harnesses and connected components or loads. On the grounds of prevailing resonances, the resulting RLC system is an oscillatory circuit. Excitation of the system results in a voltage oscillation at the terminals of connected components. One option for the damping of critical voltage oscillations is the integration of passive bandpass filters in the on-board power supply system. The design of an individual passive bandpass filter by the parameterization of resistance R, inductance L and capacitance C, as the filter parameters thereof, can be algorithmically implemented. In principle, in the majority of cases, a high capacitance delivers a superior voltage stability, although the resulting power loss generated in a passive filter is also greater. Conversely, the parameterization of multiple bandpass filters which are present in an on-board power supply system-for example in various power distributors-is substantially more complex, as multiple bandpass filters can exert a mutual influence upon one another.

In order to reduce the impacts of highly dynamic power fluctuations, multi-stage bandpass filters can be employed. Martin Baumann, Ali Shoar Abouzari, Christoph Weissinger, Bjørn Gustavsen and Hans-Georg Herzog, in: “Passive Filter Design Algorithm for Transient Stabilization of Automotive Power Systems”, 2021 IEEE 93^{rd} Vehicular Technology Conference (VTC2021—Spring), 25^{th}-28^{th} April 2021, Helsinki, Finland, thus describe the increasing expansion of the on-board vehicle power supply system to incorporate high-dynamic power electronics. These components can potentially result in malfunctions or failures of safety-related low-voltage components. In many cases, susceptibility to faults is reduced by the employment of over-dimensioned passive input electronics. In the above-mentioned publication, an alternative means of fault suppression by the incorporation of system-integrated adaptive passive filters is envisaged. A proposed method is envisaged for investigating the suitability of potential access points within complex systems. An algorithmic method for the parameterization of multiple switchable bandpass filter stages is explained. In-vehicle measurements demonstrate the effectiveness of the dimensioned filter, which can reduce faults at 70 kHz by more than 75%. The above-mentioned publication, in its full scope, is included in the present disclosure.

An object of the present disclosure is to at least partially overcome the disadvantages of the prior art and, in particular, to provide an on-board power supply system of a motor vehicle having a plurality of distributed frequency filters, wherein the frequency filters assume a particularly low power loss and generate a good voltage stability of terminal voltages of safety-critical components of the on-board power supply system.

This object is fulfilled according to the features disclosed herein. In particular, preferred embodiments can be inferred from the present disclosure.

This object is fulfilled by a method for designing a plurality of frequency filters which are distributed in an on-board power supply system of a vehicle, comprising at least the following steps:
(a) Setting up a simulation model of the on-board power supply system with a given number of frequency filters at defined locations or access points of the on-board power supply system;
(b) Determining an initial set of filter parameters of the frequency filters;
(c) Calculating the simulation model, using the set of filter parameters in the time domain;
(d) Extracting safety-critical trajectories from the calculated simulation model, together with underlying interference functions;
(e) Transforming the safety-critical trajectories from the time domain into the frequency domain;
(f) Determining transfer functions in the s-domain, by system identification;
(g) Extracting pairs of residuals and poles on the basis of transfer functions in the s-domain;
(h) Determining an energy loss value and a voltage stability value on the basis of extracted residuals and poles;
(i) Varying the set of filter parameters of the frequency filters;
(j) Repeating steps (c) to (h) using the set of filter parameters varied in step (i), until a termination criterion is achieved;
(k) Further to the achievement of the termination criterion: selecting, from a set of points having the energy loss values and voltage stability values determined in step (h), a point that lies on a pareto-front of the set of pareto- optimized points.

By this method, an advantage is achieved, in that an optimized set of filter parameters for an on-board power supply system having multiple frequency filters can be identified, wherein interactions between frequency filters are also considered.

The vehicle can be, for example, a vehicle having a combustion engine, a hybrid vehicle, or a fully electrically powered vehicle. The vehicle can be, for example, a land vehicle such as a passenger car, a motorcycle, a bus, a heavy goods vehicle, etc., an aircraft such as an airplane, a helicopter etc., or a watercraft such as a ship, etc. The on-board power supply system is employed for supplying energy to components or loads which are connected thereto. In principle, components are arbitrary, and can comprise safety-related (“ASIL”) and/or non-safety-related comfort (“QM”) components. Safety-related components can include e.g. an integrated braking system, an electric power steering system, or a windshield wiper motor, whereas comfort components can include e.g. an electric fan, a rear axle steering system, etc.

A frequency filter is employed for reducing a voltage oscillation in the power distributor which lies outside a permissible frequency band. To this end, in principle, frequency filters, or the filter stages thereof, can be configured with, or in the form of arbitrarily appropriate frequency filters, e.g. in the form of a bandpass, band-stop, low-pass and/or high-pass filter. In particular, the frequency filters or filter stages are passive filters, in particular passive bandpass filters. In particular, classification of the frequency filter as a passive filter includes the facility for the expression or definition of the filter characteristic thereof by filter parameters in the form of the filter stage resistance, filter stage capacitance and filter stage inductance. In particular, the filter stage frequency corresponds to the mid-frequency of the associated passband.

A frequency filter can comprise one or more filter stages. The determination of filter stages comprises a determination of filter parameters for each of the filter stages and, in consequence, can also be understood as the determination of filter stage parameters. Determination of the set of filter parameters of the frequency filter comprises the determination of a specific selection of filter (stage) parameters of all the filters (filter stages). According to a further development, filter stages of the multi-stage frequency filter are permanently switched on. According to a further development, filter stages of the multi-stage frequency filter can be optionally switched on and off by respective switches, in particular electronic switches.

In principle, the set-up of a simulation model for an electrical system, in particular for an on-board power supply system, according to step (a), is known, and is described, for example, in chapter III of the publication of Martin Baumann et al. The model of the on-board power supply system comprises interference sources and interference sinks. An interference source can be, for example, a load or an energy source such as, e.g. a DC voltage converter, a comfort component and/or a high-dynamic safety-related (ASIL) component which is/are capable of generating high-dynamic power fluctuations in the on-board power supply system. An interference sink can be, for example, a highly susceptible and/or safety-related load, such as an integrated braking system, an electric power steering system, a windshield wiper motor, sensors or computing devices. An interference sink can also be a power supply, such as a DC voltage converter. A component can simultaneously be an interference source and an interference sink. Interference sources, interference sinks and frequency filters are connected at various access points of the on-board system. The frequency filter is connected to the electrical path, in order to reduce interference, particularly interference which is generated by interference sources on interference sinks, e.g. on the connecting terminals thereof.

Calculation of the simulation model using the set of filter parameters in the time domain or in the time range, in the first execution cycle of step (c), comprises the initial set of filter parameters selected in step (b) and, in further execution cycles, then comprises the set which has previously been varied in step (j).

In particular, a “safety-critical” trajectory is to be understood as a characteristic of a terminal voltage u (t) on a highly susceptible and/or safety-critical component in response to a characteristic of an interference function, in the form of an interference current i (t), which is generated by an interference source. If the model comprises nq interference sources and ns interference sinks, nₜ=(nₛ·n_{g}) safety-critical trajectories. The extraction executed in step (d) corresponds to a calculation by the model in the time domain.

The transformation in step (e), for example, can comprise a Fourier transform function, e.g. a discrete Fourier transform, or DFT.

The determination of transfer functions in the mathematical s-domain, by system identification and the extraction of pairs of residuals and poles by reference to transfer functions in the s-domain can be executed, for example, in an analogous manner to the approximative method described in chapter III of the publication of Martin Baumann et al. Typically, for each approximating transfer function in the s-domain (where s is a Laplace variable), multiple pairs of residuals and poles are extracted or determined, see e.g. the publication of Martin Baumann et al., chapter III, section (1), in which e.g. N=4 pairs, wherein the original transfer function, in many cases, is approximated with a high degree of accuracy. In particular, the approximating function is a sum of polynomial fractional summands, in an analogous manner to section (1) of the publication of Martin Baumann et al.

The typically multiple pairs of residuals and poles for all transfer functions, and thus for all safety-critical trajectories, are employed in step (h) to determine or calculate a single energy loss value E_{L} and a single voltage stability value Qᵤ for the current set of filter (stage) parameters. This corresponds to a point in a diagram having the energy loss E_{L} generated by the frequency filters and the voltage stability Qᵤ of the terminal voltages of the safety-critical components considered, by way of axes.

Variation of the set of filter parameters of the frequency filter (stages) in step (i) comprises the alteration of at least one filter (stage) parameter, in relation to the preceding set.

In principle, the termination criterion in step (j) is arbitrarily selectable, and can comprise, for example, an achievement of a stipulated number of repetitions of steps (c) to (h) and/or an undershoot of a margin between two sequential points.

Further to the achievement of the termination criterion, in step (k), in particular, a set of points is determined, each having the energy loss values EL and voltage stability values Qᵤ determined in step (h), i.e. such that one point corresponds to an energy loss value and a voltage stability value pair determined in the same cycle. The number of the set of points corresponds to the number of repetitions, in addition to the initial execution cycle.

From the set of points, by known pareto-optimization methods, the pareto-front (also described as the pareto-set) can be identified which comprises the group of pareto-optimized points. From this group, one point can be selected, in order to permit the specific definition of filter (stage) parameters of the frequency filter (stages). This is possible, as a respective set of filter parameters is saved for each point in the (EL; Qu) space.

According to one configuration, the set of filter parameters is varied by an optimization method. The advantage of a particularly rapid calculation of pareto-optimized points is achieved accordingly.

According to one configuration, the set of filter parameters is varied by the particle swarm optimization method. Particle swarm optimization is particularly appropriate for the optimization problem at issue, i.e. in that a rapid convergence is provided. Particle swarm optimization, or PSO, describes a fundamentally known nature-analogous optimization method, in which a solution to an optimization problem is sought by reference to the model of biological swarm behavior. In principle, however, other multi-criterion optimization methods, such as memetic algorithms, pareto-search, global search, etc., can also be employed.

According to one configuration, for the execution of step (b), a solution space is defined in a sub-step (b1) which comprises potential values of filter parameters of the frequency filters, based upon values for filter resistances, filter capacitances and filter inductances which are available in practice and, in a sub-step (b2), the initial set of filter parameters is identified from the solution space. The advantage of a particularly practice-based design of filter parameters is thus achieved. The solution space of this simulation model is defined by maximum values and minimum values of passive components, such as resistance, capacitance and inductance, which are available for the constitution of the filter. Stray resistances associated with capacitance and inductance are also involved. Values for the resistance, capacitance and inductance of a filter stage are not restricted to the values of individually available components, but can also comprise series-and/or parallel-connected arrangements thereof.

According to a further development, the bandpass frequency of passive bandpass filters lies within a stipulated frequency range, in particular within a range of 10 kHz to 150 kHz.

According to one configuration, the initial set of parameters is selected according to a marginal stability condition having a respective maximum filter (stage) capacitance, a marginal equilibrium condition having a minimum filter (stage) capacitance, or a marginal loss condition having a target filter (stage) capacitance between the marginal stability condition and the marginal equilibrium condition. The marginal stability condition generates relatively high losses with particularly stable filtering, the marginal equilibrium condition generates relatively low losses with a higher frequency selectivity, and the marginal loss condition represents a compromise between these two extremes. Consequently, selection of the marginal stability condition generates an advantage, in that an on-board power supply system having a particularly high, in particular a maximum stability Qᵤ is considered accordingly. Consequently, selection of the marginal equilibrium condition generates an advantage, in that an on-board power supply system having particularly low, in particular minimum losses E_{L} is considered accordingly. Selection of the marginal loss condition advantageously generates a point between the two above-mentioned points.

According to a further development, the initial set of filter parameters is identified according to one of the three above-mentioned marginal conditions, and the next two variations are selected in step (i) according to the two other marginal conditions. An advantage is thus achieved, in that three starting points are provided in the (E_{L}; Qᵤ) space which, from the outset, form a highly advantageous starting configuration, such that the selected optimization algorithm assumes a rapid convergence. In turn, this facilitates a subsequent optimization of filter parameters and shortens a computing time required for the calculation of further pareto- optimized points. It is thus particularly advantageous if steps (c) to (h) are initially executed with the three marginal conditions, and a variation of the set of filter parameters, by an optimization method, is only executed with effect from the fourth execution cycle of steps (c) to (h).

According to one configuration, for the parameterization of frequency filters, initial values of filter parameters for the individual frequency filters are determined by algorithmic calculations. The algorithmic determination of initial parameters for the individual frequency filters can be executed, for example, according to the method described in chapter IV of the publication of Martin Baumann et al.

According to one configuration, the initial set of filter parameters is arbitrarily identified from the solution space. Advantageously, this is particularly simple, but may extend the overall time required for executing the method. According to a further development, at least one set of filter parameters which follows the initial set is arbitrarily varied. According to a further development, sets which follow a specific number of arbitrarily varied sets are varied by an optimization method, such that the arbitrarily varied sets form only a sub-quantity of sets upon which a subsequent optimization is based. The specific number can be e.g. three.

The object is also fulfilled by an on-board power supply system of a vehicle having a plurality of distributed frequency filters, wherein filter parameters of the frequency filters have been determined according to the above-mentioned method. The on-board power supply system can be configured in an analogous manner to the method, and vice versa, and comprises the same advantages. In particular, frequency filters are designed according to the set of filter parameters which define the point selected on the pareto-front according to step (k) of the above-mentioned method.

According to one configuration, at least one of the frequency filters is integrated in a power distributor. This provides an advantage, in that a particularly limited number of frequency filters is required, and in that frequency filters can be integrated in the on-board power supply system in a particularly simple manner. The function of the power distributor is the connection of multiple electrical components (loads, consumer devices, etc.) to the on-board power supply system and, to this end, the power distributor particularly comprises respective sub-circuits having corresponding terminals or connecting terminals. In principle, connectable components are arbitrary, and can comprise safety-related (ASIL) and/or non-safety-related comfort (QM) components.

In particular, the power distributor is an “electronic” power distributor, to the effect that at least a proportion of sub-circuits and, in particular, all the sub-circuits to which respective electrical components are connectable are protected by a respective electronic fuse.

According to one configuration, at least one of the frequency filters is a multi-stage filter. This provides an advantage, in that prevailing resonances in the on-board power supply system can be filtered in a particularly effective manner, particularly with respect to safety-related components such that, for example, a stabilization of the terminal voltages thereof in response to the occurrence of current/power transients is achieved.

According to one configuration, the on-board power supply system is a low-voltage on-board power supply system, in particular a low-voltage on-board power supply sub-system. The low-voltage on-board power supply system, for example, can assume a rated voltage between 12 V and 60 V. In the event that the on-board power supply system is a low-voltage on-board power supply sub-system, the latter can form part of an overall on-board power supply system which also incorporates a high-voltage on-board power supply sub-system, e.g. having a rated voltage which is higher than the rated voltage of the low-voltage on-board power supply sub-system, e.g. between 48 V and 800 V, or even higher.

The object is also fulfilled by a vehicle having an on-board power supply system of the above-mentioned type. The on-board power supply system can be configured in an analogous manner to the on-board power supply system, and vice versa, and comprises the same advantages. The vehicle can thus comprise an overall on-board power supply system, which incorporates both the low-voltage on-board power supply sub-system and a high-voltage on-board power supply sub-system, wherein the low-voltage on-board power supply sub-system, according to a further development, can be supplied with electrical energy from the high-voltage on-board power supply sub-system.

According to one configuration, the vehicle is a fully electrically powered vehicle or a battery powered vehicle. The method or on-board power supply system is particularly advantageous for this purpose, on the grounds that, in fully electrically powered vehicles, the stability of the on-board power supply system is particularly important.

The above-mentioned properties, features and advantages of the present disclosure, and the manner in which these are achieved, are further explained and clarified in conjunction with the following schematic description of an exemplary embodiment, which is described in greater detail with reference to the drawings.

### BRIEF DESCRIPTION OF THE DRAWINGS

FIGS. 1(A) and 1(B) show a section of an equivalent circuit diagram of a potential on-board power supply system of a vehicle, having a plurality of frequency filters;

FIG. 2 shows an abstracted equivalent circuit diagram of a multi-stage frequency filter of the on-board power supply system according to FIGS. 1(A) and 1(B);

FIG. 3 shows a potential sequence of a method for designing the filter parameters of frequency filters of the on-board power supply system according to FIGS. 1(A) and 1(B);

FIG. 4 shows a plot of a voltage oscillation in a (V,t) diagram; and

FIG. 5 shows an (E_{L};Qᵤ) diagram having (E_{L};Qᵤ) points which are obtained according to the method.

### DETAILED DESCRIPTION OF THE DRAWINGS

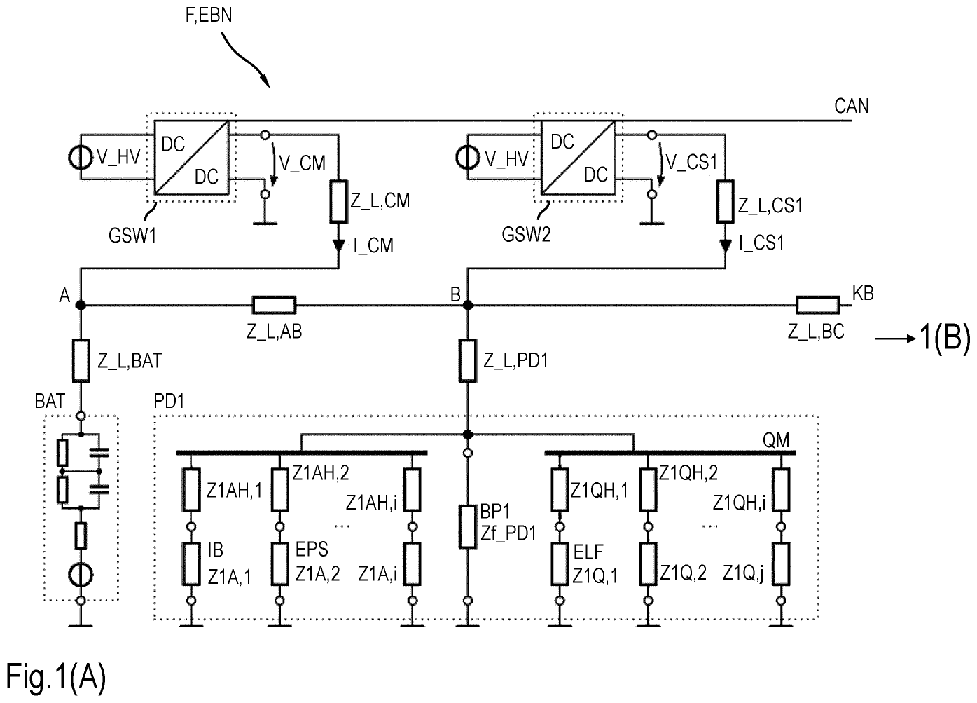

FIG. 1, by reference to the sub-images FIG. 1(A) and FIG. 1(B) thereof, shows a section of an equivalent circuit diagram of an on-board power supply system EBN of a vehicle F. The on-board power supply system EBN comprises a low voltage (LV) on-board power supply sub-system, which can be supplied from a high-voltage (HV) on-board power supply sub-system having a HV system voltage VHV, in the present case via a plurality of galvanically isolated DC voltage converters GSW1, GSW2, GSW3. The DC voltage converters GSW1, GSW2, GSW3 convert the higher HV system voltage VHV of the HV on-board power supply sub-system into a respective lower LV voltage V_CM, V_CS1 or V_CS2. The DC voltage converters GSW1, GSW2, GSW3 are connected to a communication channel of the vehicle F, in the present case e.g. a CAN-bus CAN, and can communicate with one another via the communication channel. In particular, the DC voltage converters GSW1, GSW2, GSW3 can be provided in a master-slave arrangement, wherein e.g. the DC voltage converter GSW1 is employed as a master, and the DC voltage converters GSW2, GSW3 are employed as slaves.

In the present case, the LV voltages V_CM, V_CS1 and V_CS2 are applied, via a respective node A, B or C, to a locally extended cable harness KB of the LV on-board power supply sub-system, by conductors having respective line impedances Z_L,CM, Z_L,CS1 or Z_L,CS2. Adjoining nodes A and B, B and C, etc. of the extended cable harness KB are typically separated from one another by line sections having line impedances Z_L,AB, Z_L,BC, etc.

A battery BAT is further connected to the cable harness KB, in the present case, exemplarily, at the node A, via a conductor having a line impedance Z_L,BAT.

Moreover, multiple electrical components are connected to the cable harness KB of the LV on-board power supply sub-system, via at least one (in the present case, two) power distributor(s) PD1, PD2. In the present case, the power distributors PD1 and PD2 are connected to the nodes B or C via the line impedances Z_L,PD1 or Z_L,PD2. Via individual sub-circuits, both safety-related (ASIL) components, such as an integrated braking system IB, an electric power steering system EPB, a windshield wiper motor WIP, etc., and comfort (QM) components, such as an electric fan ELF and a rear axle steering system RAS, can be connected to the power distributors PD1, PD2. In the present case, impedances present in the individual sub-circuits are plotted as line impedances Z_MNH,P and as impedances Z_MN,P of connected components, wherein “M” represents the number of the power distributor PD1, PD2, “N” is the designation of a sub-circuit, in which “A” represents an ASIL component and “Q” represents a comfort component, and “P” represents the number of the ASIL or comfort component in a respective power distributor PD1, PD2.

In order to prevent interference, particularly with safety-related components IB, EPB, WIP, in each power distributor PD1, PD2, a multi-stage bandpass filter BP1 or BP2 (with respective impedances Zf,PD1 or Zf,PD2), each having a plurality of selectively connectable and disconnectable stages FSⱼ, is electrically arranged in parallel with the respectively connected electrical component. The filters BP1 and BP2 can be of an identical design, or can be differently configured—for example with respect to the number and/or filter properties of the filter stages FSⱼ.

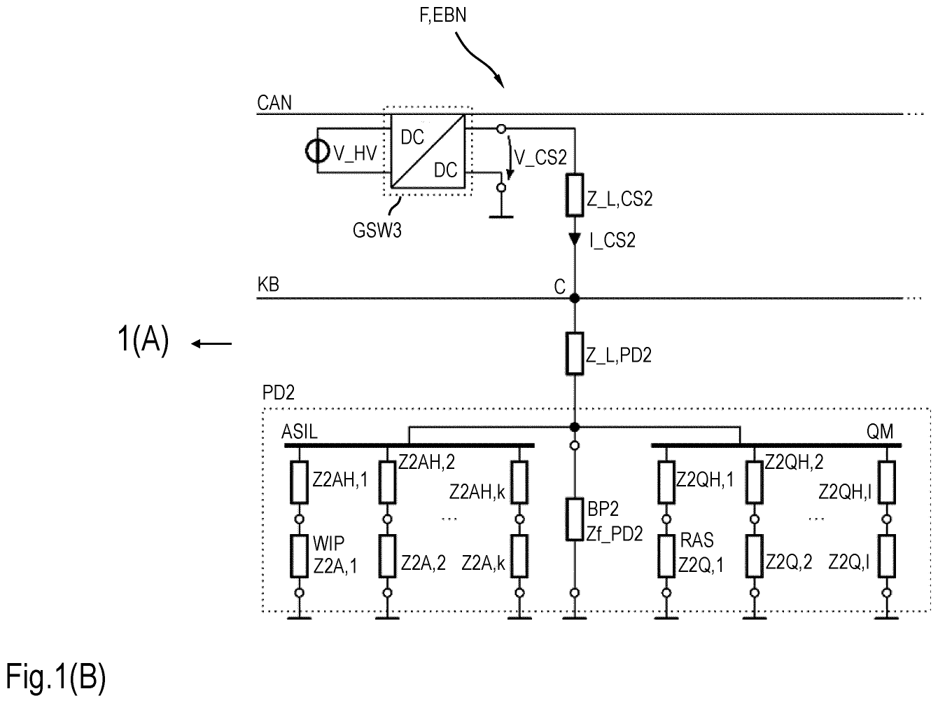

The multi-stage bandpass filter BP1, BP2, and electrical components IB, EPB, WIP, ELF, RAS which are connected to the power distributors PD1, PD2, are protected by respective electronic fuses or “eFuses” Efi (see FIG. 2).

In principle, in the LV on-board power supply sub-system, one or more power distributors PDi can be present, wherein i≥1, i.e. more than two power distributors PD1, PD2.

In particular, at least one safety-related component IB, EPB, WIP and/or at least one comfort component ELF, RAS can be connected to each of the power distributors PDi.

In order to further reduce interference with components-particularly including safety-related components-IB, EPB, WIP, ELF, RAS, etc., further (unrepresented) frequency filters and/or electronic fuses can be provided in the associated individual sub-circuit, which are specifically intended to protect the respective components IB, EPB, WIP, ELF, RAS, etc. These further frequency filters, in the event of the presence of the filters BP1 and BP2, can advantageously be configured with a lower rating than in the absence of the filters BP1 and BP2.

FIG. 2 shows an abstracted equivalent circuit diagram of a multi-stage passive bandpass filter BPi which is integrated in one of the power distributors PDi incorporating the on-board power supply system EBN. The filter BPi is optionally protected by a low-impedance electronic fuse EFi, which can optionally be switched to a conducting or a non-conducting state by the switch Q_{fuse}. The electronic fuse EFi is located in the same sub-circuit as the bandpass filter BPi, and is advantageously arranged up-circuit thereof, optionally being installed in a common module with the bandpass filter BPi.

The multi-stage filter BPi comprises k=1, . . . , kₘₐₓ (in the present case, kₘₐₓ>2) parallel-connected bandpass filter stages FSₙ, each having a fixed parameterized combination of an ohmic resistance Rₙ, an electrical inductance Lₖ and an electrical capacitance Cₖ, the values of which can be considered as filter parameters. Optionally, by respective electronic switches Qₖ, the bandpass filter stages FSₖ can optionally be connected to, or disconnected from the power supply system. In the present case, the electronic switches Qₖ are configured in the form of low-impedance MOSFETs.

The filter stages FSₙ are protected against short-term voltage pulses by a bidirectional suppressor diode D₁ which is internal to the multi-stage filter BPi.

The electronic switch Qₖ is actuated by a gate driver GT of the power distributor PDi, which gate driver, in turn, is adjusted by a control device ECU of the power distributor PDi, e.g. in the form of a microcontroller. The control device ECU, via the CAN-bus CAN, receives variations with respect to a circuit state of the LV on-board power supply sub-system. The control device ECU compares a variation of the circuit state, or of the present circuit state of the LV on-board power supply sub-system with a database, in particular with a look-up table which is saved therein, in which a corresponding discrete (circuit) configuration of the filter BPi is assigned to each potential circuit state of the LV on-board power supply sub-system. In particular, a discrete configuration of the filter BPi is understood as a specific combination of conducting/non-conducting circuits of the electronic switches Qⱼ. To this end, the configuration of the filter BPi which is saved for a specific circuit state of the LV on-board power supply sub-system is the discrete configuration of the filter BPi which is most appropriate for suppressing resonances in the LV on-board power supply sub-system under this circuit state of the LV on-board power supply sub-system. In particular, for each circuit state of the LV on-board power supply sub-system, there is thus exactly one filter parameterization of the filter BPi, which is established by the associated switch-on or switch-off of the stages FSₖ. In other words, the control device ECU interprets or ascertains the associated configuration of the electronic switches Qₖ of the filter BPi by reference to information with respect to the circuit state of the LV on-board power supply sub-system which is communicated via the CAN-bus CAN.

The discrete circuit state of the filter BPi which is retrieved by the control device ECU is relayed to the gate driver GT, which switches the electronic switches Qₖ accordingly.

A system voltage Vₛ corresponds to the voltage which is detected on the power distributor PDi between the node points B, C thereof, or similar, and the local reference potential (ground).

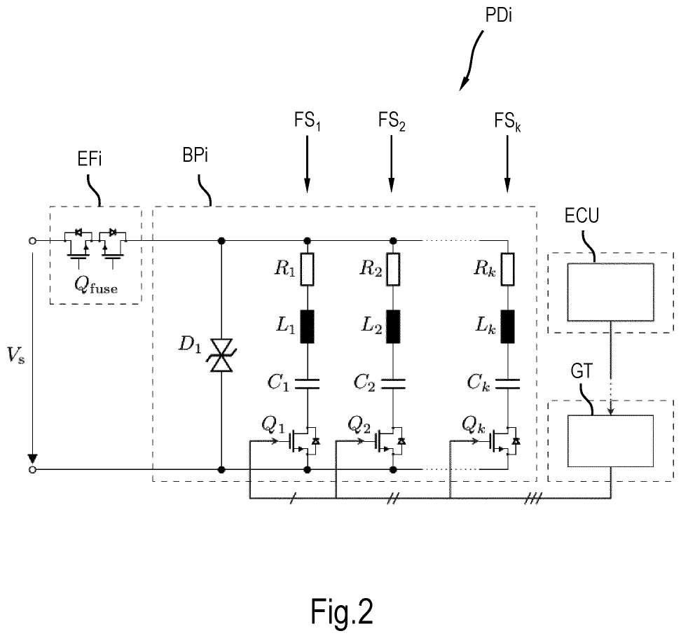

FIG. 3 shows a potential sequence for designing the filter parameters Rₙ, Lₖ and Cₖ of the frequency filters BP1, BP2, or BPi.

In a step S1, e.g. in the PYTHON programing language, a simulation model is set up of an on-board power supply system, e.g. of the on-board power supply system EBN, having a given number of frequency filters BP1, BP2 or BPi at specific locations or access points of the on-board power supply system.

In a step S2, a solution space is defined, which comprises potential values of the filter parameters Rₙ, Lₖ and Cₖ of the frequency filters BP1, BP2, or BPi, or of the filter stages FS₁, FS₂, FSₖ thereof, on the basis of values for filter resistances, filter capacitances and filter inductances which are available in practice.

In a step S3, from the solution space, an initial set of filter parameters Rₙ, Lₖ and Cₖ for all the frequency filters BP1, BP2, or BPi, or for the filter stages FS₁, FS₂, FSₖ thereof, is identified, for example according to a marginal stability condition, a marginal equilibrium condition or a marginal loss condition.

In a step S4, the initial set of filter parameters Rₙ, Lₖ and Cₖ is employed in the simulation model, which employment can also be described as the parameterization of the simulation model.

In a step S5, the parameterized simulation model is processed, i.e. compiled for employment in a simulation calculation environment, e.g. using Modelica, an object-oriented modeling language for physical models and, in a step S6, is then calculated in the simulation calculation environment, in the time domain.

From the calculation executed in step S6, safety-critical trajectories are generated, which trajectories are extracted and, together with underlying interference functions, are transformed or converted into complex safety-critical trajectories in the frequency domain, in a step S7.

In a step S8, by system identification (e.g. by conversion into MATLAB runtime), transformed trajectories are employed for determining or calculating corresponding transfer functions in the mathematical s-domain, where s is a Laplace variable.

In a step S9, from transfer functions in the s-domain, in each case, at least one pair, typically multiple pairs of residuals r (designated as “cₙ” in the publication of M. Baumann et al.) and poles p (designated as “aₙ” in the publication of M. Baumann et al.) are extracted, in particular by the employment of an approximating transfer function in the s-domain.

In a step S10, from all the extracted pairs of residuals and poles, a value of an energy loss E_{L} and a value of a voltage stability Qᵤ are calculated, which values can also be understood as coordinate values of a point in a corresponding (E_{L};Qᵤ) diagram. Each point corresponds to a specific set of filter parameters Rₙ, Lₖ and Cₖ for all the filters BPi or filter stages FS₁ of the on-board power supply system EBN considered.

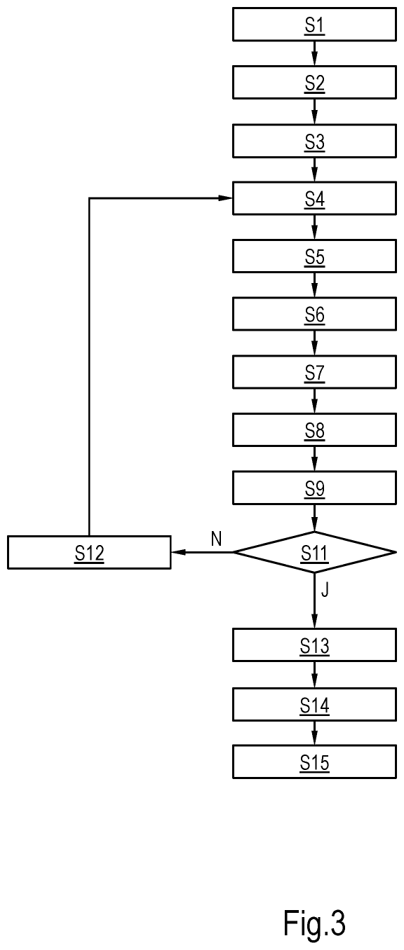

In particular, this sequence can be implemented with regard to the following considerations:
i) The on-board power supply system EBN assumes an advantageous voltage stability, in the event that a high load fluctuation on interference sources influences terminal voltages on interference sinks to a limited extent only. The concept of this definition of voltage stability is visualized in FIG. 4. A step of e.g. 1 A on an interference source/load results in a voltage oscillation U_{TF}(t), which decays over a time t, on the terminals of the interference sink considered. The voltage oscillation U_{TF}(t) assumes a specific amplitude, a transient recovery time tₛ, and a voltage-time integral Q_{u,t}. This voltage-time integral Qᵤₜ is employed for the quantification of voltage stability. Accordingly, both the step response amplitude and the transient recovery time tₛ are considered.
ii) To this end, complex poles p identified in step S9 are investigated with respect to their oscillating tendency. For an individual pair, comprised of a complex pole p and its corresponding complex remainder or residual r, a transfer function G_{PF}(s) of the second order is constituted according to:

$${G}_{P F} ( s ) = \frac{r}{s - p} + \frac{\overline{r}}{s - \overline{p}} = \frac{r ( s - \overline{p} ) + \overline{r} ( s - p )}{{s}^{2} - s ( p + \overline{p} ) + p \overline{p}}$$

wherein s describes the Laplace coordinate, r the complex residual, p the complex pole,
r̅ the complex conjugated residual, and
p̅ the complex conjugated pole.
iii) This transfer function G_{PF}(s) is transformed from the mathematical s-domain into the time domain, thus giving the voltage oscillation U_{TF}(t) according to:

$${u}_{P F} ( t ) = \frac{{K}_{1}}{{ω}^{2}} ( {e}^{- D ω T} [ cos ( F t ) + Asin ( F t ) ] - 1 )$$

$$ω = \sqrt{Re {\{ p \}}^{2} + Im {\{ p \}}^{2}}$$

$$D = - \frac{Re \{ p \}}{ω}$$

$${K}_{1} = - 2 ( Re \{ p \} Re \{ r \} + Im \{ p \} Im \{ r \} )$$

$${K}_{2} = 2 Re \{ r \}$$

$$F = ω \sqrt{1 - {D}^{2}}$$

$$A = \frac{D {K}_{1} - ω {K}_{2}}{{K}_{1} \sqrt{1 - {D}^{2}}}$$

where

From the voltage oscillation u_{TF}(t), the envelope uₑₙᵥ(t) thereof is derived:

$${u}_{e n v} ( t ) = \frac{{K}_{1}}{{ω}^{2}} ( {e}^{- D ω t} K - 1 )$$

wherein the trigonometric expressions in u_{TF}(t) are replaced by a constant κ. Trigonometric expressions describe an oscillation having a specific frequency and amplitude. The amplitude corresponds to the maximum value of expressions, and is set at a time point t=tₚₖ, wherein the following applies:

$$cos ( F t ) + Asin ( F t ) = max$$

$$for t = {t}_{p k}$$

$$K = cos ( F {t}_{k} ) + Asin ( F {t}_{p k} )$$

The voltage-time integral Qᵤₜ for a specific pair of residuals r and poles p corresponds to the (V,t) integral between the envelope uₑₙᵥ(t) and the value uₛₛ represented by a broken line in FIG. 4 for the steady-state condition, until a stipulated termination criterion εᵥ is achieved. The termination criterion can represent a specific fraction, e.g. 1%, of the envelope Uₑₙᵥ(t) at t=0. This can be implemented e.g. according to εᵥ=1% of [Uₑₙᵥ(t=0)−uₛₛ].
iv) The envelope Uₑₙᵥ(t) and values uₛₛ for the steady-state condition of all (oscillating) (r,p) pairs which are associated with a specific approximating transfer function, and thus with a specific safety-critical trajectory, are added, and a trajectory-specific voltage-time interval Q_{u,p} is calculated therefrom, as described above. This process is executed for all nₜ=(nₛ·n_{q}) safety-critical trajectories.
v) The voltage stability Qᵤ of the on-board power supply system EBN as a whole, in the present exemplary embodiment, comprises the trajectory-specific transient voltage-time integrals Q_{u,p} of all nₜ=(nₛ·n_{q}) safety-critical trajectories. It can then be defined as the sum of the voltage-time integrals Q_{u,p}, according to:

$${\sum }_{p = 1}^{{n}_{t}} {Q}_{u , p}$$

v) The energy loss E_{L} generated by the current set of filter parameters in the on-board power supply system EBN can be defined, for example, according to:

$${E}_{L} = {\sum }_{f = 0}^{{n}_{f}} {\sum }_{s = 0}^{{n}_{f , s}} {\int }_{0}^{{t}_{s}} {{i}_{f , s} ( t )}^{2} {R}_{f , s} d t$$

E_{L} is the energy loss generated by the filters and filter stages in the entire on-board power supply system EBN. This energy loss can be calculated, as described above, as an integral of the product of the quadratic current i_{f,s}(t) in a filter stage (wherein f is the filter index and s is the filter stage index), multiplied by the stipulated filter stage resistance R_{f,s} over the transient recovery time tₛ. The current i_{f,s}(t) flowing in the filter stage FSₛ of the filter BPf can be calculated according to the above-mentioned equations, e.g. in consideration of the voltage oscillation U_{TF}(t).

This integral is then totalized over all n_{f,s} filter stages of all n_{f} filters, in order to obtain the energy loss E_{L}.

In step S11, a check is executed as to whether a specific termination criterion is fulfilled. If this is not the case (“N”), in step S12, the set of filter parameters Rₙ, Lₖ and Cₖ are varied, and a transition to step S4 is executed. Variation can be executed, for example, such that, for the initial filter parameters Rₙ, Lₖ and Cₖ, values are employed which fulfil the marginal stability condition, values for the second and third execution cycles of steps S4 to S9 are employed which correspond to the marginal equilibrium condition or to the marginal loss condition, and subsequent variations in step S12 are executed on the basis of the particle swarm optimization method. However, in the event of a positive response to this check (“J”), in step S13, the pareto-front is determined from the set of (E_{L}; Qᵤ) points.

In step S14, a point which lies on the pareto-front is selected. Accordingly, the underlying set of filter parameters Rₙ, Lₖ and Cₖ associated with this point is also identified, and can then be employed, for example in a step S15, for the constitution of a corresponding on-board power supply system EBN.

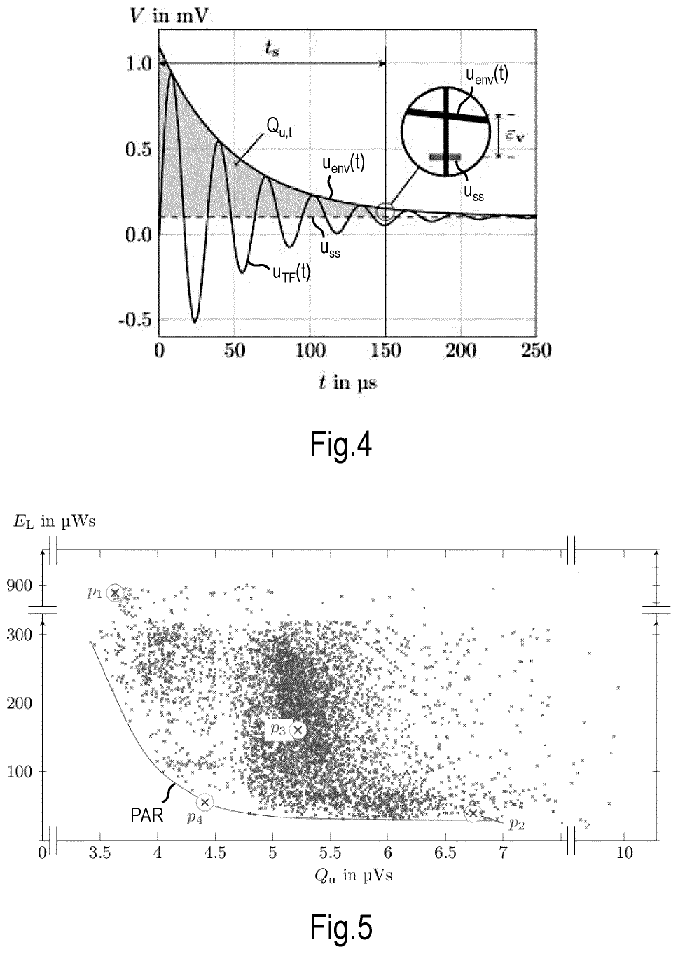

FIG. 5 shows an (E_{L}; Qᵤ) diagram which is employable in step S13, in the form of a plot of the energy loss E_{L} in μWs against the voltage stability Qᵤ in μVs, having a plurality of (E_{L};Qᵤ) points. Points on the pareto-front PAR correspond to an optimum parameterization of frequency filters. Point p1 thus corresponds to the parameter set for the marginal stability condition, point p2 to the parameter set for the marginal equilibrium condition, and point p3 to the parameter set for the marginal loss condition. Parameter sets for further points are determined by particle swarm optimization. Point p4 corresponds to a point on the pareto-front PAR, and can be selected e.g. as a point for the specific parameterization of the on-board power supply system EBN.

Naturally, the present disclosure is not limited to the exemplary embodiment represented.

In general, the terms “a”, “an”, etc. can be understood as a singularity or a plurality, particularly within the meaning of “at least one”, “one or more”, etc., provided that this is not explicitly excluded, e.g. by the employment of the term “exactly one”, etc.

Indication of number can comprise exactly the number indicated, or can incorporate a customary tolerance margin, provided that this is not explicitly excluded.

1-12. (canceled)

13. A method for designing a plurality of frequency filters that are distributed in an on-board power supply system of a vehicle, the method comprising:
(a) setting up a simulation model of the on-board power supply system with a given number of frequency filters at defined locations of the on-board power supply system;
(b) determining an initial set of filter parameters of the frequency filters;
(c) calculating the simulation model using the set of filter parameters in time domain;
(d) extracting safety-critical trajectories from the calculated simulation model, together with underlying interference functions;
(e) transforming the safety-critical trajectories from the time domain into the frequency domain;
(f) determining transfer functions in a mathematical s-domain, by system identification;
(g) extracting pairs of residuals and poles on a basis of transfer functions in the s-domain;
(h) determining an energy loss value and a voltage stability value on a basis of the extracted residuals and poles;
(i) varying the set of filter parameters of the frequency filters;
(j) repeating steps (c) to (h) using the set of filter parameters varied in step (i), until a termination criterion is achieved; and
(k) further to the achievement of the termination criterion, selecting, from a set of points having energy loss values and voltage stability values determined in step (h), a point that lies on a pareto-front of the set of points.

14. The method according to claim 13, wherein,
in step (j), the set of filter parameters is varied by an optimization method.

15. The method according to claim 14, wherein,
in step (j), the set of filter parameters is varied by a particle swarm optimization method.

16. The method according to claim 13, wherein,
step (b) comprises:
(b1) defining a solution space that comprises potential values of filter parameters of the frequency filters, based upon values for filter resistances, filter capacitances, and filter inductances that are available in practice; and
(b2) identifying the initial set of filter parameters from the solution space.

17. The method according to claim 16, comprising:
selecting the initial set of filter parameters according to a marginal stability condition having a maximum filter stage capacitance, a marginal equilibrium condition having a minimum filter stage capacitance, or a marginal loss condition having a target filter stage capacitance between the marginal stability condition and the marginal equilibrium condition.

18. The method according to claim 16, comprising:
arbitrarily identifying the initial set of filter parameters from the solution space.

19. An on-board power supply system of a vehicle having a plurality of distributed frequency filters, wherein the frequency filters are designed according to the set of filter parameters which define the point selected on the pareto-front in step (k) of the method according to claim 13.

20. The on-board power supply system according to claim 19,
wherein at least one of the frequency filters is integrated in an electronic power distributor.

21. The on-board power supply system according to claim 19,
wherein at least one of the frequency filters is a multi-stage filter.

22. The on-board power supply system according to claim 19,
wherein the on-board power supply system is a low-voltage on-board power supply system.

23. A vehicle comprising:
the on-board power supply system according to claim 19.

24. The vehicle according to claim 23,
wherein the vehicle is a fully electrically powered vehicle.
